(19) United States
(12) Patent Application Publication
(10) Pub. No.: US 2007/0293048 A1
(43) Pub. Date: Dec. 20, 2007

(54) Polishing slurry

(76) Inventors: Jon-won Lee, Seongnam-si (KR); Chang-ki Hong, Seongnam-si (KR); Bo-un Yoon, Seoul (KR)

Correspondence Address: LEE & MORSE, P.C., 3141 FAIRVIEW PARK DRIVE, SUITE 500, FALLS CHURCH, VA, 22042, US

(21) Appl. No.: 11/812,140

(22) Filed: Jun. 15, 2007

(30) Foreign Application Priority Data
Jun. 19, 2006 (KR) 10-2006-0055029

(51) Int. Cl. H01L 21/461; B24D 3/02; C09K 3/14

(52) U.S. Cl. 438/692; 51/307; 438/693

(57) ABSTRACT

A polishing slurry, including an oxidizer, a corrosion inhibitor, and a polishing rate enhancer, wherein the polishing rate enhancer is a heterocyclic compound having at least one nitrogen in the ring, and the nitrogen is not directly bonded to a hydrogen atom which is mostly dissociated in the slurry.

### BACKGROUND OF THE INVENTION

1. Field of the Invention

Embodiments of the present invention relate to a polishing slurry and a method of manufacturing a semiconductor device using the same. More particularly, embodiments of the present invention relate to a polishing slurry suitable for polishing a metal interconnection, and a method of manufacturing a semiconductor device using the same.

2. Description of the Related Art

As semiconductor devices achieve higher performance and higher degrees of integration, a multi-level interconnection structure has been one approach used to advance the design and manufacture of the semiconductor devices. In a multi-level interconnection structure, a CMP (chemical mechanical polishing) process may be employed to planarize a base layer, so as to facilitate performing of a subsequent process such as a photolithography process. The CMP process may be performed after completing a predetermined process such as a dielectric layer forming process or a metal interconnection forming process in the manufacture of the semiconductor device. Typically, a polishing slurry is employed to improve the polishing performance and efficiency of the CMP process.

In general, a CMP process combines both a chemical action and a mechanical action. The chemical action derives from one or more reactive chemicals in the slurry. The mechanical action derives from one or more abrasives (polishing particles) in the slurry and/or a mechanical action of a polishing device, e.g., a polishing pad. In a typical CMP process, a CMP polishing slurry is supplied to a region between a wafer surface and a rotating polishing pad during the CMP process, so that the mechanical action is performed by abrasive particles in the slurry and surface protrusions on the polishing pad, and the chemical action, i.e., chemical removal, is performed by one or more chemical components in the slurry.

With the trend toward a reduction in the line width and an increase in packaging density in interconnection technology, there have been continued attempts to enhance the performance of semiconductor devices by solving various limiting factors for achieving highly integrated devices, such as RC delay, signal dispersion or crosstalk noise. In accordance with this trend, copper, tungsten, and aluminum have been focused on as conductive materials for interconnects. In addition, in order to increase the insulating property of interconnections, a material having a low dielectric constant k, (a “low-k dielectric”), e.g., a material having a dielectric constant of approximately 2 to approximately 2.7, has become a focus of much interest as an interlayer insulating film material.

However, a layer made of a low-k dielectric material may be porous, and thus may exhibit poor performance during a CMP process, e.g., suffering scratches, etc. The occurrence of scratches may be caused by the presence of an abrasive. One approach to solving this problem is to use a slurry that is substantially free of abrasive or has abrasive in a low concentration. Such a slurry, however, may exhibit poor performance in mechanical polishing action due to the low concentration of abrasive, which may undesirably reduce the polishing rate. One approach to offsetting the reduced performance that results from low abrasive concentrations is to include an oxidizer in the slurry. However, increasing the amount of the oxidizer contained in the slurry may pose several problems, including the occurrence of scratches, pits, corrosion, erosion, and/or dishing. Thus, it may be desirable to include a corrosion inhibitor as a slurry additive for purposes of suppressing corrosion of a metal interconnection, i.e., to prevent a dishing phenomenon from occurring to the metal interconnection by suppressing the corrosion of the metal interconnection. Nonetheless, such a slurry may exhibit a low polishing rate.

### SUMMARY OF THE INVENTION

The present invention is therefore directed to a polishing slurry and a method of manufacturing a semiconductor device using the same, which substantially overcome one or more of the problems due to the limitations and disadvantages of the related art.

It is therefore a feature of an embodiment of the present invention to provide a slurry that includes a polishing rate enhancer that improves a polish and/or etch rate when combined with a corrosion inhibitor.

It is therefore another feature of an embodiment of the present invention to provide a slurry that includes a polishing rate enhancer and a corrosion inhibitor, and which may contain a relatively small amount of abrasive.

At least one of the above and other features and advantages of the present invention may be realized by providing a polishing slurry, including an oxidizer, a corrosion inhibitor, and a polishing rate enhancer, wherein the polishing rate enhancer is a heterocyclic compound having at least one nitrogen in the ring, and the nitrogen is not directly bonded to a hydrogen atom which is mostly dissociated in the slurry.

The nitrogen in the ring of the heterocyclic compound may have an unshared electron pair. The corrosion inhibitor may be a heterocyclic aromatic hydrocarbon compound having a nitrogen in the ring, and the nitrogen in the ring of the corrosion inhibitor may be directly bonded to a hydrogen atom and may be mostly dissociated in the slurry.

The polishing rate enhancer may be 1-aminopyrazole, 3-amino-1,2,4-triazine, aminothiazole, 2-amino 1,3,4 thiadiazole, 2-aminothiazoline, 2-aminopyrimidine, or 1-(3-aminopropyl)imidazole.

The polishing rate enhancer may be a pyrimidine, pyrazole, pyridazine, pyrazine, pyridine, triazine, thiazole, thiadiazole or an imidazole compound. The polishing rate enhancer may include an amino group. The polishing rate enhancer may include exactly one or two amino groups. The corrosion inhibitor may be a triazole or tetrazole compound. The concentration of the polishing rate enhancer in the slurry may be approximately 0.001 mole/L to approximately 0.5 mole/L. The concentration of the corrosion inhibitor in the slurry may be approximately 0.001 mole/L to approximately 0.1 mole/L.

The oxidizer may be a peroxide. The amount of the oxidizer in the slurry may be approximately 0.1 wt % to approximately 10 wt %, based on the total weight of the slurry. The slurry may further include an inorganic acid, the oxidizer may be hydrogen peroxide, the amount of the oxidizer in the slurry may be approximately 0.1 wt % to approximately 10 wt %, based on the total weight of the slurry, and the amount of the inorganic acid in the slurry may be approximately 0.5 wt % to approximately 5 wt %, based on the total weight of the slurry. The slurry may further include a metal oxide removing compound that includes a carboxyl group. The concentration of the metal oxide removing compound in the slurry may be 0.001 mole/L to approximately 0.1 mole/L.

The slurry may further include an abrasive. The amount of the abrasive in the slurry may not be greater than approximately 1 wt %, based on the total weight of the slurry.

At least one of the above and other features and advantages of the present invention may be realized by providing a method of manufacturing a device, including forming a metal pattern on an insulating layer, and planarizing the metal pattern using a slurry, wherein the slurry includes an oxidizer, a corrosion inhibitor, and a polishing rate enhancer, wherein the polishing rate enhancer is a heterocyclic compound having at least one nitrogen in the ring, and the nitrogen is not directly bonded to a hydrogen atom which is mostly dissociated in the slurry.

At least one of the above and other features and advantages of the present invention may be realized by providing a semiconductor device manufactured according to a method of the present invention as described herein.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1 and 2 illustrate graphs of variations in current density with addition of corrosion inhibitors;

FIG. 3 illustrates a graph of results of variations in current density with addition of polishing rate enhancers;

FIGS. 4 and 5 illustrate graphs of variations in current density with addition of corrosion inhibitors and polishing rate enhancers; and

FIGS. 6-9 illustrate particular comparative experimental examples and experimental examples according to embodiments of the present invention.

### DETAILED DESCRIPTION OF THE INVENTION

Korean Patent Application No. 10-2006-0055029, filed on Jun. 19, 2006, in the Korean Intellectual Property Office, and entitled: “Slurry for Polishing Metal Interconnection,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Embodiments of the present invention provide a polishing slurry, which may be employed to manufacture a device having a metal interconnection in a stable manner by suppressing excessive corrosion of the metal interconnection while enhancing the polishing rate of the metal interconnection. As used herein, a slurry means a product obtained by dispersing or dissolving constituents in a solvent such as deionized water. The metal interconnection may include, e.g., copper, tungsten, aluminum, etc. In an embodiment of the present invention, the slurry may include an oxidizer, a corrosion inhibitor, and a polishing rate enhancer.

The oxidizer may oxidize a feature of the device being polished, e.g., it may oxidize a metal interconnection of the device being polished. The oxidizer may include one or more peroxide-type compounds, e.g., hydrogen peroxide, benzoyl peroxide, calcium peroxide, barium peroxide, and/or sodium peroxide. Hydrogen peroxide may afford desirable oxidizing ability and dispersion stability in the slurry.

In an implementation, the slurry may further include one or more inorganic oxidizers, which may be used in combination with the above-described oxidizer. The inorganic oxidizer may increase the oxidizing ability of the slurry. The inorganic oxidizers may include, e.g., nitric acid, sulfuric acid, hydrochloric acid and/or phosphoric acid. Where nitric acid is employed, it may advantageously produce little or no contamination after polishing. The inorganic oxidizer may also serve as a pH adjuster for adjusting the pH of the slurry.

The amount of oxidizer in the slurry may be approximately 0.1 weight percent (wt %) to approximately 10 wt %, e.g., approximately 0.5 wt % to approximately 5 wt %, based on the total weight of the slurry. Where the slurry includes such an amount of oxidizer, side effects due to excessive oxidization, such as erosion, corrosion, pit corrosion, or dishing, etc., may be reduced while maintaining an appropriate polishing rate. The amount of inorganic oxidizer in the slurry may be approximately 0.001 wt % to approximately 1 wt %, e.g., approximately 0.001 wt % to approximately 0.5 wt %, based on the total weight of the slurry.

The corrosion inhibitor included in the slurry may partially or completely suppress corrosion of the metal interconnection during the CMP process. In an embodiment of the present invention, the corrosion inhibitor may be a compound having at least one nitrogen atom in an aromatic ring and the nitrogen atom may be directly bonded to a hydrogen atom which is easily dissociable into a hydrogen ion in the slurry. The corrosion inhibitor may include one or more of a triazole-based compound and/or a tetrazole-based compound, and derivatives thereof, e.g., 1,2,3-benzotriazole and/or 5-aminotetrazole.

To suppress corrosion of the metal interconnection while maintaining polishing efficiency, the amount of corrosion inhibitor in the slurry may be approximately 0.001 to approximately 0.1 mole/L, e.g., approximately 0.001 to approximately 0.05 mole/L.

The polishing rate enhancer included in the slurry may be a compound containing at least one nitrogen atom in an aromatic ring, where a hydrogen atom, which is dissociable into a hydrogen ion in the slurry, is not directly bonded to the nitrogen atom contained in the aromatic ring and has at least one unshared electron pair. The polishing rate enhancer may include one or more of pyrimidine, pyrazole, pyridazine, pyrazine, pyridine, triazine, thiazole, thiadiazole, and/or imidazole-type compounds, e.g., 1-aminopyrazole, 3-amino-1,2,4-triazine, aminothiazole, 2-amino-1,3,4-thiadiazole, 2-aminothiazoline, 2-aminopyrimidine, and/or 1-(3-aminopropyl)imidazole.

To maintain the dispersion stability and the performance of the slurry, and considering cost efficiency of the CMP process, the amount of polishing rate enhancer in the slurry may be approximately 0.001 mole/L to approximately 0.5 mole/L, e.g., approximately 0.005 mole/L to approximately 0.05 mole/L. Using too low a concentration of the polishing rate enhancer may result in a polishing rate enhancing effect that is low. Using a concentration of the polishing rate enhancer that exceeds the range specified above may not produce considerable increases in the polishing rate.

Proposed mechanisms for the interaction of the corrosion inhibitor and the polishing rate enhancer with the feature being polished will now be described. However, it will be appreciated that embodiments of the present invention are not limited to any particular mechanism of interaction.

The following reaction schemes 1A-1B describe a proposed mechanism for the interaction of the corrosion inhibitor in the slurry with the feature being polished, using a copper feature as an example. The corrosion inhibitor may be dissolved in the slurry and may donate a hydrogen, so as to be negatively charged. The corrosion inhibitor may combine with the metal (the metal interconnection, i.e., the polishing target material) in a polymer-like structure that passivates the surface of the metal. In this case, a strong ionic bond may be created between the metal and the corrosion inhibitor.

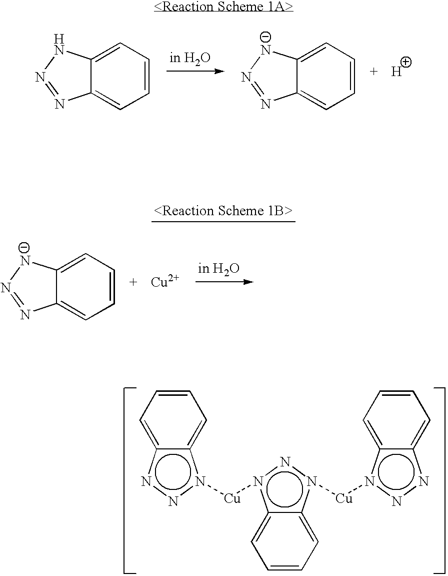

The following reaction schemes 2 and 3 describe proposed mechanisms for the interaction of polishing rate enhancers in the slurry with the feature being polished, using a copper feature as an example in each reaction scheme. A nitrogen atom in the ring of the polishing rate enhancer is not directly bonded to a hydrogen atom, which is mostly dissociated in the slurry. Accordingly, the polishing rate enhancer may be neutralized in the slurry, unlike the corrosion inhibitor that is negatively charged in the slurry. In addition, since at least one unshared electron pair is provided by the nitrogen atom of the polishing rate enhancer, the nitrogen atom may form a coordinate bond with a metal ion through the unshared electron pair, and this bond may be weaker than the ionic bond between the corrosion inhibitor and the metal ion. Here, the unshared electron pair does not contribute to aromaticity. Where the polishing rate enhancer includes an amino group (—NH₂), a hydrogen atom of the amino group may not be readily dissociated, i.e., it may be mostly protonated in the slurry, and may not be directly bonded to a nitrogen atom contained in the aromatic ring.

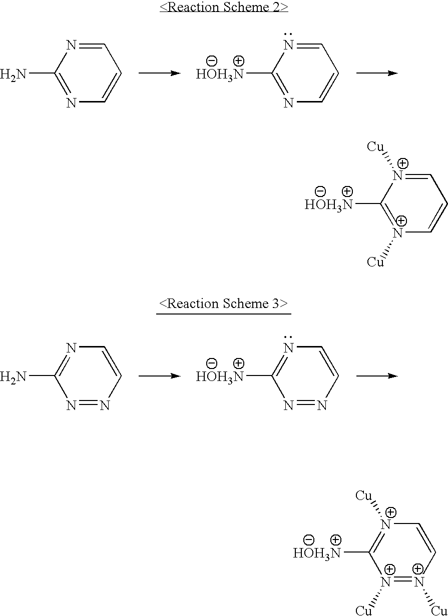

Unlike the above-described corrosion inhibitor, the polishing rate enhancer may bond with oxidized metal ions in the slurry without causing polymerization. Accordingly, the polishing rate enhancer may prevent the oxidized metal ions in the slurry from being redeposited on the metal interconnection in the form of an oxide film. Further, unlike the corrosion inhibitor, the polishing rate enhancer may not passivate the metal interconnection.

As described above, the polishing rate enhancer may effectively remove the metal ions in the slurry without passivating the metal interconnection. This may increase the CMP process speed, thereby enhancing processing efficiency.

In an exemplary embodiment of the present invention, the polishing rate enhancer may include one or more amino groups as substituents of the mother nucleus structure. The amino groups may increase the density of electrons relative to nitrogen atoms in the mother nucleus structure and adjust the solubility of the polishing rate enhancer in the slurry. If an excessive number of amino groups are attached to the aromatic ring, steric hindrance may occur, which may undesirably inhibit bonding between the polishing rate enhancer and the metal ions. In an implementation, the polishing rate enhancer may have up to two amino groups.

In an embodiment of the present invention, the slurry may further include a metal oxide removing agent. The metal oxide removing agent may prevent metal components dissolved from the metal interconnection by the oxidizer from being redeposited on the metal interconnection in the form of an oxide film, e.g., CuₓO_{y} or Cuₓ(OH)_{y} for copper, due to binding with oxygen or hydroxide atoms contained in the slurry. The metal oxide removing agent may also remove a metal oxide film redeposited on the metal interconnection.

Metal oxide removing agents may include, e.g., one or more carboxyl group-containing compounds such as acetic acid, citric acid, formic acid, maleic acid, malic acid, malonic acid, tartaric acid, glutaric acid, oxalic acid, propionic acid, phthalic acid, and/or succinic acid.

The metal oxide film, which may be formed on a metal film during the CMP process, may prevent the metal film from being exposed to the oxidizer. In consideration of the thickness of the metal oxide film and process efficiency, the metal oxide removing agent may be present in the slurry in a concentration of approximately 0.001 mole/L to approximately 0.1 mole/L, e.g., approximately 0.005 mole/L to approximately 0.05 mole/L.

In an embodiment of the present invention, the slurry may further include an abrasive. Where the feature to be polished includes a low-k dielectric material layer, the slurry may contain a low concentration of the abrasive or no abrasive at all.

A metal oxide-based abrasive may be used as the abrasive. The metal oxide-based abrasive may include one or more of, e.g., alumina, silica, titania, zirconia, ceria, and/or germania.

In consideration of process efficiency, the particle size of the abrasive may be approximately 5 nm to approximately 1000 nm, e.g., approximately 10 nm to approximately 500 nm. Where the feature to be polished includes a low-k dielectric material layer, the content of the abrasive in the slurry may not be greater than approximately 1 wt %, e.g., not greater than approximately 0.5 wt %, based on the total weight of the slurry. Where the feature to be polished does not include a low-k dielectric material layer, the content of the abrasive in the slurry may be increased.

In an embodiment of the present invention, the slurry may further include one or more additives for polishing metal interconnections, e.g., a pH adjuster and/or a dispersion stabilizer.

The pH adjuster may adjust a pH of the slurry to an appropriate range, for example, a pH of approximately 2 to approximately 12. The pH adjuster may include one or more of, e.g., sulfuric acid, phosphoric acid, hydrochloric acid, nitric acid, carboxylic acid, potassium hydroxide, ammonium hydroxide, and/or sodium hydroxide.

The dispersion stabilizer may include, e.g., anionic surfactants, such as a polymer having a molecular weight of approximately 1,000 to approximately 1,000,000, a co-polymer, a ter-polymer, etc. The polymer may include, e.g., poly(acrylic acid), or a salt thereof. The co-polymer may include, e.g., poly(acrylic acid)-co-maleic acid, or a salt thereof. The ter-polymer may include, e.g., polyacrylonitrile-co-butadiene-acrylic acid, or a salt thereof.

Slurries for polishing a metal interconnection according to exemplary embodiments of the present invention may provide an increased polishing rate of the metal interconnection during a CMP process, thereby improving the manufacturability of semiconductor devices. In addition, the slurries may allow the metal interconnection to be formed in a stable manner by suppressing excessive corrosion of the metal interconnection. The occurrence of scratches, which may be caused by abrasive particles, may be avoided by reducing an amount of abrasive used. The slurries may be prepared for use using slurry preparation techniques that are generally used in the art. Further, the slurries may be used in place of conventional slurries in conventional metal interconnection polishing processes.

Polishing performance and etching characteristics of slurries according to exemplary embodiments of the present invention were evaluated. The following comparative experimental examples and experimental examples demonstrate the results of these evaluations.

### COMPARATIVE EXPERIMENTAL EXAMPLE 1

### Dependence of Polishing Rate and Etch Rate on Corrosion Inhibitors Added

To evaluate the polishing rate and etch rate dependence on corrosion inhibitors, comparative samples having the compositions listed in FIG. 6 were prepared. Sample wafers used in the evaluation were copper blanket wafers, which were prepared by sequentially depositing 3000 Å thick PE-TEOS (plasma enhanced tetraethylorthosilicate) as a buffer oxide film, 100 Å thick Ta, 250 Å thick TaN and a 1,200 Å thick Cu seed layer on a poly-Si substrate by chemical vapor deposition (CVD), followed by forming a 12,000 Å thick copper film by an electroplating process.

The etch rates were measured in a static state. The etch rates were determined by measuring resistance values before and after dipping samples in test solutions for 20 minutes. The equipment used in the evaluation was a POLI-380 tester for 6-inch wafers (manufactured by G&P Tech., Korea). The evaluation was carried out under the following conditions: down pressure of 2.5 psi, platen speed of 80 rpm, head speed of 75 rpm, and slurry flow rate of 250 ml/min.

The polishing rate was determined by measuring a difference in the thickness of a tested wafer before and after the evaluation using a 4-point probe-type resistivity measuring device.

The results of the evaluation are set forth in FIG. 6. The results obtained using slurries containing corrosion inhibitors (in Comparative Samples 2 through 4) were compared with results obtained using the slurry containing no corrosion inhibitor (in Comparative Sample 1). As illustrated in FIG. 6, when the corrosion inhibitors were included in the slurries, both the polishing rate and the etch rate decreased. The decreases in the polishing rate and the etch rate are thought to be due to the etch and polishing-reducing effect exhibited by the resulting product of a reaction between the corrosion inhibitors on the copper surface and copper ions. In addition, compared to a case where only a corrosion inhibitor was included in the slurry (Comparative Sample 3), when both a corrosion inhibitor and an abrasive were included in the slurry (Comparative Sample 4), the polishing rate was increased while the etch rate was reduced.

### COMPARATIVE EXPERIMENTAL EXAMPLE 2

### Dependence of Polishing Rate and Etch Rate on Polishing Rate Enhancers Added

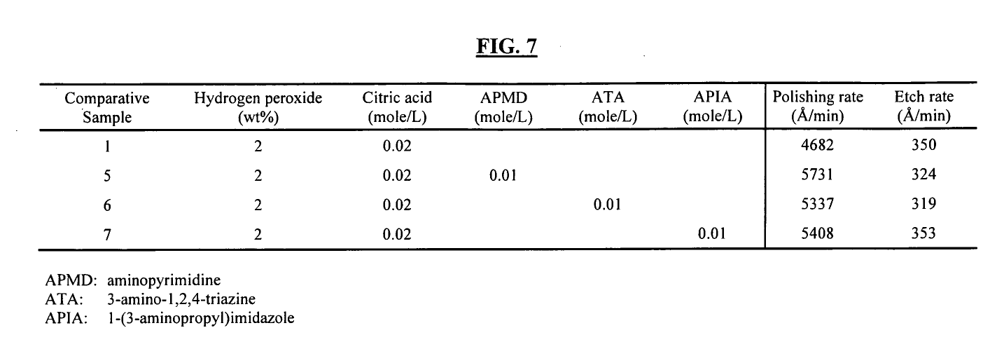

To evaluate the polishing rate and etch rate depending on polishing rate enhancers added, three kinds of slurries having different compositions were prepared. To eliminate effects of an abrasive on the polishing rate and etch rate, no abrasive was added to the prepared slurries. However, it will be appreciated that embodiments of the present invention are not limited to abrasive-free slurries. The evaluation was carried out in the same manner as in the Comparative Experimental Example 1, and the results of the evaluation for the respective slurries are set forth in FIG. 7.

The results obtained using slurries containing polishing rate enhancers (in Comparative Samples 5 through 7) were compared with results obtained using the slurry containing no polishing rate enhancer (in Comparative Sample 1). As illustrated in FIG. 7, when the polishing rate enhancers were included in the slurries, both the polishing rate and the etch rate increased. It is apparent that, although the polishing rate enhancer and the corrosion inhibitor may be similar in structure, they exhibit significantly different behavior in the slurry.

### COMPARATIVE EXPERIMENTAL EXAMPLE 3

### Electrochemical Properties of Corrosion Inhibitor and Polishing Rate Enhancer

The corrosion inhibitors and polishing rate enhancers were evaluated electrochemically. Electrochemical experiments were done through chronoamperometry (CA) using an EG&G model No. 263A potentiostat/galvanostat, by which a change in the current density can be measured on the copper surface in real time with addition of corrosion inhibitors and polishing rate enhancers. The experiments were carried out in the following manner. A copper (Cu) electrode acting as a working electrode, a platinum (Pt) electrode acting as a counter electrode, and a saturated calomel electrode (SCE) acting as a reference electrode, each having a surface area of 0.5 cm², were placed in a blank solution containing neither corrosion inhibitor nor polishing rate enhancer, and a potential of about 0.5 V was applied to the working electrode to randomly dissolve copper. After a lapse of a predetermined time, e.g., about 40 seconds, solutions containing a corrosion inhibitor and/or a polishing rate enhancer were added to the blank solution, and a change in the current density was measured on the copper surface. To ensure dynamic behavior observations, the test solutions were maintained in dynamic states using magnet stirring bars. In this way, changes in the current density could be observed on the copper surface in a real-time basis with addition of the corrosion inhibitors and the polishing rate enhancers.

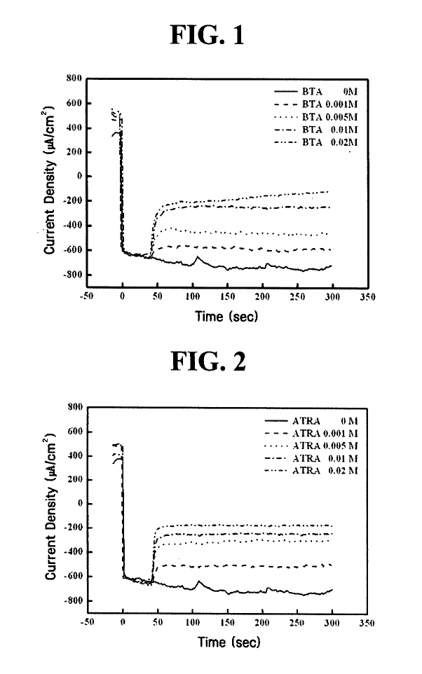

To evaluate actions of the corrosion inhibitors, a blank solution was prepared from an aqueous solution containing deionized water as a solvent, 0.01 M of citric acid and 2 wt % of H₂O₂ and adjusted to pH 4. BTA (1,2,3 benzotriazole) or ATRA (5-aminotetrazole) was added to the prepared blank solution in concentrations of 0.001, 0.005, 0.01, and 0.02 mole/L. The results of the evaluation are shown in FIGS. 1 and 2.

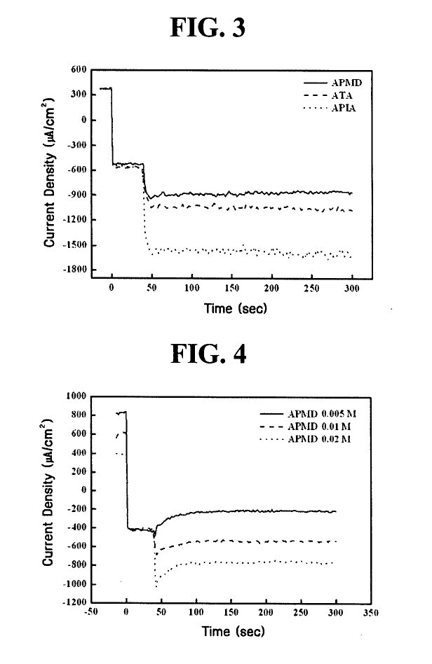

To evaluate actions of the polishing rate enhancer, the same blank solution was used as that used in the evaluation of the actions of the corrosion inhibitors, and APIA (1-(3-aminopropyl)imidazole), ATA (3-amino-1,2,4-triazine), and APMD (aminopyrimidine) were added to the blank solution in a concentration of 0.01 mole/L, respectively. The results of the evaluation are shown in FIG. 3.

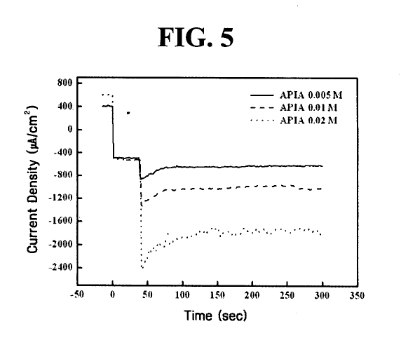

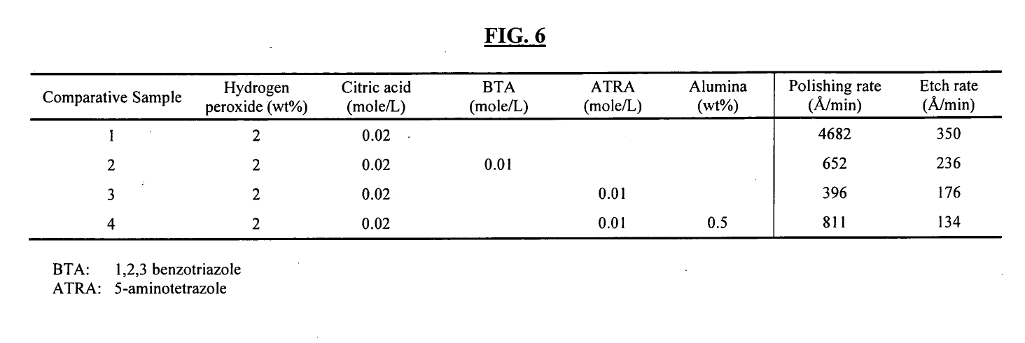

When the corrosion inhibitor and the polishing rate enhancer were both included in the slurry, to evaluate actions of the respective additives, the same blank solution as above was used, 0.01 mole/L ATRA was used as the corrosion inhibitor, and APMD and APIA were used as the polishing rate enhancers in concentrations of 0.005, 0.01, and 0.02 mole/L, respectively. The results of the evaluation are shown in FIGS. 4 and 5.

Referring to FIGS. 1 and 2, the copper surface showed a reduction in the current density with addition of the solutions containing the corrosion inhibitors to the blank solution. Also, it was ascertained that the higher the concentration of the corrosion inhibitor in the solution, the more the reduction in the current density. Accordingly, the results indicate that the corrosion inhibitor provides the effect of passivating the copper surface, and resultant films produced after the passivating become thicker as the amount of the corrosion inhibitor added increases.

Referring to FIG. 3, addition of the solutions each containing a polishing rate enhancer significantly increased the current density across the copper surface. The polishing rate enhancers may bond with oxidized copper ions in the slurries so that the copper ions are dissolved in the solutions, thereby preventing the copper ions in the slurries from being redeposited on the copper surface.

Referring to FIGS. 4 and 5, considerable increases in the current density corresponded to increasing concentrations of the polishing rate enhancers. Also, the amount of the increases in the current density were dependent upon the kinds of the polishing rate enhancers added.

### EXPERIMENTAL EXAMPLE 1

### Etch Rates of Metal Films

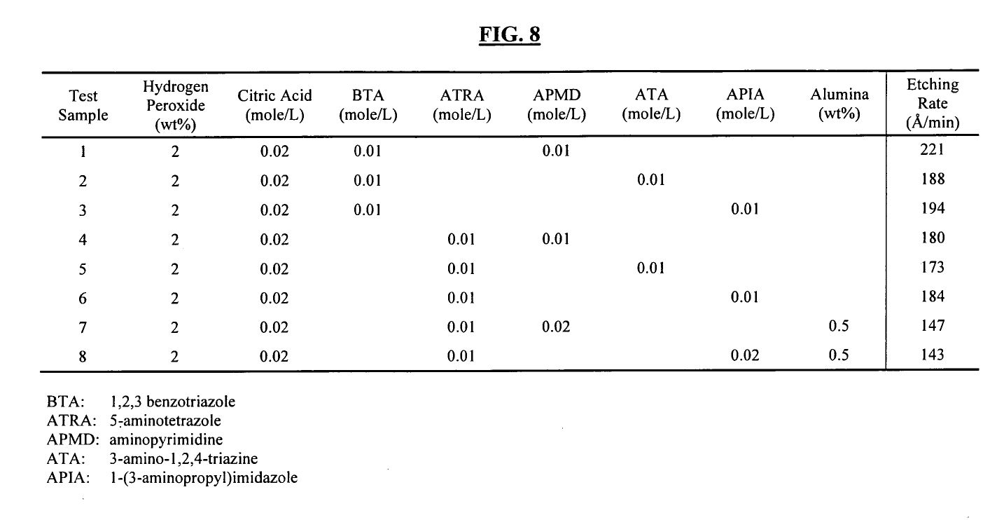

To evaluate etch rates of metal films with addition of corrosion inhibitors and polishing rate enhancers according to exemplary embodiments of the present invention, six kinds of slurries having different compositions were prepared. The evaluation was carried out in substantially the same manner as in the Comparative Experimental Example 1, and the results of the evaluation for the respective slurries are set forth in FIG. 8.

As illustrated in FIG. 8 (test samples 1 through 8), in cases where each of a corrosion inhibitor and a polishing rate enhancer were included in the slurry, the etch rate of the copper film did not show a considerable increase, compared to cases where only a corrosion inhibitor was included in the slurry (in Comparative Samples 2 through 4 of Comparative Experimental Example 1). Thus, the reaction speed of the corrosion inhibitor on the copper surface may be relatively faster than that of the polishing rate enhancer.

### EXPERIMENTAL EXAMPLE 2

### Polishing Rates of Copper Films

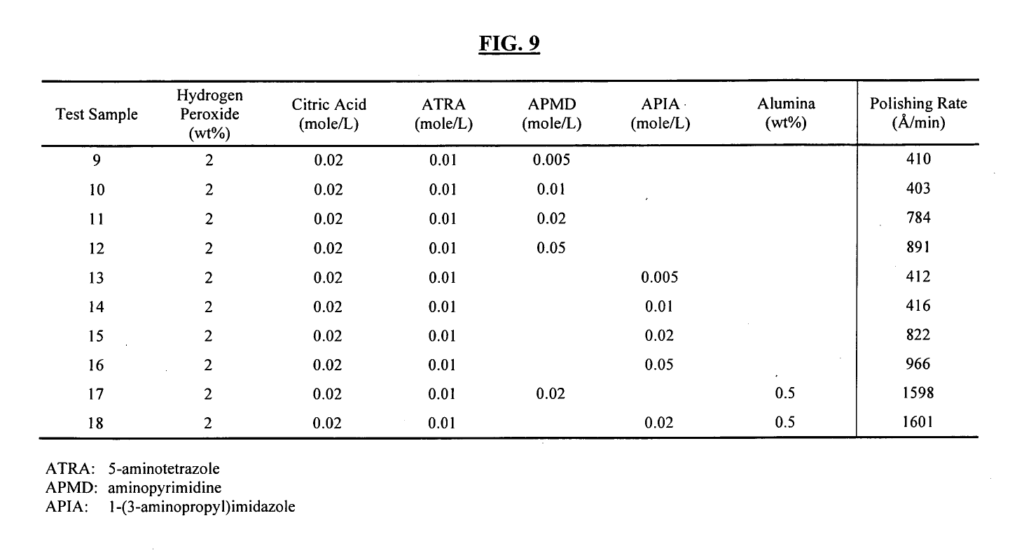

In this example, to evaluate polishing rates of copper films with addition of corrosion inhibitors and polishing rate enhancers according to exemplary embodiments of the present invention, substantially the same evaluation procedure was carried out as in the Comparative Experimental Example 1. Results of the evaluation for the respective slurries are set forth in FIG. 9.

As illustrated in FIG. 9, compared to a case of a slurry containing ATRA as the corrosion inhibitor without a polishing rate enhancer (in Comparative Sample 3 of Comparative Experimental Example 1), when a polishing rate enhancer was added to the slurry, like in test samples 9 through 18, copper polishing rates were enhanced. In addition, it was found that the copper polishing rates were substantially improved at higher concentrations of the polishing rate enhancer.

Further, the copper polishing rates in cases where alumina, as an abrasive, and a polishing rate enhancer were included in the slurries, as in Test Samples 17 and 18, were much faster than in Comparative Sample 4 of Comparative Experimental Example 1 and Test Samples 11 and 15.

As described above, according to the above-described embodiments of the present invention, even if a slurry for polishing a metal interconnection is substantially free of an abrasive or contains a reduced amount thereof, the slurry enables the metal interconnection to be manufactured by the conventional semiconductor manufacturing process in a stable manner. Slurries according to embodiments of the present invention may suppress excessive corrosion of the metal interconnection while enhancing the polishing rate of the metal interconnection. In addition, the occurrence of scratches due to use of an abrasive may be reduced or avoided by reducing an amount of the abrasive used. Thus, various defects of the metal interconnection that occur during a CMP process may be reduced when using a low-k dielectric material layer.

As described above, slurries according to embodiments of the present invention may enhance the polishing rate of the metal interconnection in the manufacture of semiconductor devices without increasing the concentration of an abrasive. Also, slurries according to embodiments of the present invention may enable the manufacture of metal interconnections in a stable manner by suppressing excessive corrosion of the metal interconnection.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A polishing slurry, comprising:
an oxidizer;
a corrosion inhibitor; and
a polishing rate enhancer, wherein the polishing rate enhancer is a heterocyclic compound having at least one nitrogen in the ring, and the nitrogen is not directly bonded to a hydrogen atom which is mostly dissociated in the slurry.

2. The slurry as claimed in claim 1, wherein:
the nitrogen in the ring of the heterocyclic compound has an unshared electron pair.

3. The slurry as claimed in claim 2, wherein the corrosion inhibitor is a heterocyclic aromatic hydrocarbon compound having a nitrogen in the ring, and the nitrogen in the ring of the corrosion inhibitor is directly bonded to a hydrogen atom and is mostly dissociated in the slurry.

4. The slurry as claimed in claim 1, wherein the polishing rate enhancer is one selected from the group consisting of 1-aminopyrazole, 3-amino-1,2,4-triazine, aminothiazole, 2-amino-1,3,4-thiadiazole, 2-aminothiazoline, 2-aminopyrimidine, and 1-(3-aminopropyl)imidazole.

5. The slurry as claimed in claim 1, wherein the polishing rate enhancer is a pyrimidine, pyrazole, pyridazine, pyrazine, pyridine, triazine, thiazole, thiadiazole or an imidazole compound.

6. The slurry as claimed in claim 5, wherein the polishing rate enhancer comprises an amino group.

7. The slurry as claimed in claim 6, wherein the polishing rate enhancer comprises exactly one or two amino groups.

8. The slurry as claimed in claim 5, wherein the corrosion inhibitor is a triazole or tetrazole compound.

9. The slurry as claimed in claim 8, wherein the concentration of the polishing rate enhancer in the slurry is approximately 0.001 mole/L to approximately 0.5 mole/L.

10. The slurry as claimed in claim 9, wherein the concentration of the corrosion inhibitor in the slurry is approximately 0.001 mole/L to approximately 0.1 mole/L.

11. The slurry as claimed in claim 8, wherein the oxidizer is a peroxide.

12. The slurry as claimed in claim 11, wherein the amount of the oxidizer in the slurry is approximately 0.1 wt % to approximately 10 wt %, based on the total weight of the slurry.

13. The slurry as claimed in claim 11, further comprising an inorganic acid, wherein:
the oxidizer is hydrogen peroxide,
the amount of the oxidizer in the slurry is approximately 0.1 wt % to approximately 10 wt %, based on the total weight of the slurry, and
the amount of the inorganic acid in the slurry is approximately 0.5 wt % to approximately 5 wt %, based on the total weight of the slurry.

14. The slurry as claimed in claim 11, further comprising a metal oxide removing compound that includes a carboxyl group.

15. The slurry as claimed in claim 14, wherein the concentration of the metal oxide removing compound in the slurry is 0.001 mole/L to approximately 0.1 mole/L.

16. The slurry as claimed in claim 8, further comprising an abrasive.

17. The slurry as claimed in claim 16, wherein the amount of the abrasive in the slurry is not greater than approximately 1 wt %, based on the total weight of the slurry.

18. A method of manufacturing a device, comprising:
forming a metal pattern on an insulating layer; and
planarizing the metal pattern using a slurry, wherein the slurry includes:
an oxidizer;
a corrosion inhibitor; and
a polishing rate enhancer, wherein the polishing rate enhancer is a heterocyclic compound having at least one nitrogen in the ring, and the nitrogen is not directly bonded to a hydrogen atom which is mostly dissociated in the slurry.

19. A semiconductor device manufactured according to the method as claimed in claim 18.
